(19) United States
(12) Patent Application Publication
(10) Pub. No.: US 2010/0103969 A1
(43) Pub. Date: Apr. 29, 2010

(54) VERTICAL CAVITY SURFACE EMITTING LASER STRUCTURE

(76) Inventor: Timo Aalto, Helsinki (FI)

Correspondence Address: FAY SHARPE LLP, 1228 Euclid Avenue, 5th Floor, The Halle Building, Cleveland, OH, 44115, US

(21) Appl. No.: 12/520,135

(22) PCT Filed: Dec. 21, 2007
(86) PCT No.: PCT/FI2007/050718

§ 371 Date: Dec. 4, 2009

(30) Foreign Application Priority Data
Dec. 21, 2006 (FI) 20061148

(51) Int. Cl. H01S 5/183; H01S 5/065; H01S 3/08

(52) U.S. Cl. 372/45.01; 372/92

(57) ABSTRACT

A VCSEL (Vertical Cavity Surface Emitting Laser) structure (1), wherein at least one cross-section of the VCSEL structure perpendicular to the optical axis (2) of the VCSEL structure comprises a mode selecting shape (10) promoting output of the fundamental transverse mode of the resonator while suppressing output of the higher modes. According to the present invention, the mode selecting shape (10) comprises a longitudinal portion (101) being directed past the optical axis (2) and having a one-sided broadening (102) forming a central area (103) around the optical axis, the geometry of the mode selecting shape being chosen to concentrate the fundamental mode in the central area while guiding the possible higher modes away from the optical axis through the longitudinal portion.

### FIELD OF THE INVENTION

This invention relates to vertical cavity surface emitting lasers (VCSELs). More specifically, this invention relates to structures for maximising the output optical power while saving the single mode operation of a VCSEL.

### BACKGROUND OF THE INVENTION

Vertical cavity surface emitting lasers (VCSELs) are nowadays an important class of semiconductor lasers. They are commonly used in e.g. optical telecommunication networks, optical interconnections and optical measurement systems.

Unlike edge-emitting lasers, VCSELs emit light vertically, i.e. along the z-axis (when the substrate on which the component is formed extends in xy-plane). This enables the dense integration of multiple VCSELs on a single semiconductor chip, as well as the customised positioning and/or property tuning of individual VCSELs on a single semiconductor wafer. Thus, VCSELs have many essential advantages compared to alternative laser types.

As well known for those skilled in the art, a VCSEL is a layer structure formed on a semiconductor substrate and basically comprises an active layer sandwiched between a lower and an upper mirror forming an optical resonant cavity. The active layer can be, for example, a quantum well structure. There can be also spacer layers between the active layer and the mirrors. A lower and an upper electrical contact layer for applying current into the active layer are arranged on the upper and lower sides, respectively, of this layer structure.

In prior art VCSELs, all those constraining or guiding structures described above are usually based on cylindrical symmetry. In other words, said structures are intended to confine the gain and/or generated photons in a cylindrical volume around a central axis or optical axis of the device. In fact, also the entire layer structure is often formed as a cylindrical pillar structure rising from the substrate. Said confinement of the gain of the device to the optical axis can be realised, for example, by structures guiding the current flow and/or lateral shape and size of the mirrors forming the optical cavity. Optical confinement in turn can be achieved by changes in the refractive index between the central and peripheral area of the cavity. A VCSEL is then called gain-guided or index-guided, respectively.

In most cases, single mode operation of a VCSEL is desired. The vertical cavity of a VCSEL is typically so thin that it only supports one longitudinal mode. Situation is more complicated with trans-verse operation. On the other hand, another main target in designing VCSELs is as high output power as possible. In conventional VCSELs, these two requirements are contradictory as is described in the following.

Firstly, operation of a gain-guided VCSEL can be single-mode if the current is sufficiently low, the transverse gain profile is sufficiently narrow and the optical aperture of the upper contact is sufficiently small. However, when the current is increased or the aperture is made larger the gain-guided VCSEL typically becomes multi-mode. This limits the output power and the output beam width of gain-guided single-mode VCSELs. In general, an index-guided VCSEL can be single-mode if the refractive index contrast and the transverse dimensions of the intra-cavity waveguide are sufficiently small, and the current is kept sufficiently low. However, these restrictions limit the output power and the output beam width of index-guided single-mode VCSELs. In addition, for each VCSEL type there is a fundamental upper limit in possible optical power density which would, even if the high power would not give rise to multi-mode operation, necessitate a wider beam. This in turn, as mentioned above, could unfortunately easily lead to multi-mode operation.

Based on the previous discussion, it is clear that the requirement for single-mode operation limits the output power and the output beam width of typical, cylindrical symmetric VCSELs. To overcome the problem, several structures have been proposed to increase the output power and the output beam width of single-moded VCSELs, to reduce the number of modes in VCSELs, and to improve the output beam quality (or output coupling efficiency) of VCSELs. Many of these VCSEL structures are described, for example, in U.S. Pat. No. 6,751,245.

For example, the limited aperture of the upper contact can be used to partially block the output beam of higher order lasing modes, and phase elements on top of the upper mirror can be used to manipulate the output beam so that the output coupling efficiency of higher order lasing modes is reduced. However, these methods do not prevent the initial lasing of the higher order modes inside the cavity, so that the efficiency of the VCSEL is not optimised.

Some known VCSELs are claimed to operate in single-mode, although the near field intensity distribution of their output beam is significantly different from the Gaussian-like output beam of typical single-mode lasers. Sometimes additional optics outside the laser cavity is used to image such a non-Gaussian near field pattern into a more Gaussian-like intensity distribution in the far field, i.e. further away from the laser cavity. One example of such a VCSEL is reported in US Patent Application Pub. No. 2004/0228379 A1, where the near field of the laser has several intensity maxima and resembles a pearl necklace, while the far field intensity distribution is transformed into a Gaussian-like far field intensity distribution. However, in most applications the near-field of the VCSEL's output should be as Gaussian as possible. Thus, in the following discussion a VCSEL is only said to be single-mode if its near field pattern on the output side has a Gaussian-like intensity distribution with only a single significant intensity maximum and a substantially flat phase distribution, although the near field is not required to be exactly Gaussian.

Some proposed methods involve the realisation of intra-cavity structures to vary the optical thickness or the loss of the resonator in the xy-plane. For example, a patterned anti-phase layer inside the cavity can induce optical coupling from the resonating higher order modes into non-resonating radiation modes, and to prevent the lasing of any higher order transverse modes. Such a layer can have a minimal impact on the fundamental mode if it is added only to the periphery of the optical aperture, i.e. sufficiently far from the optical axis of the VCSEL. In a similar way, a patterned layer of higher absorption or lower reflection can be added into the cavity to increase the loss of higher order modes and to prevent them from lasing. However, the additional intra-cavity structures reported in the prior art have only led to limited improvements in output power and output beam quality, and these have been achieved at the cost of more complicated and expensive VCSEL fabrication. One example of this kind of approach having said disadvantages is described in US Patent Application Pub. No. 2005/0089075 A1.

Some known VCSELs include so-called Photonic crystal (PhC) structures that prevent the lasing of higher order transverse modes via the photonic bandgap effect. Examples of such VCSELs can be found e.g. in US Patent Application Publ. No. 2004/0114893 A1. However, the PhC structures typically need to have sub-wavelength dimensions that are more complicated and expensive to fabricate than the conventional VCSEL structures. Furthermore, VCSELs with PhC structures are typically more sensitive to fabrication tolerances and, because of their wavelength sensitivity, less applicable to tunable lasers.

### PURPOSE OF THE PRESENT INVENTION

It is an object of the present invention to provide a VCSEL structure providing high output power and wide near field intensity distribution with single mode operation while maintaining good output beam quality and avoiding the need for complicated or expensive fabrication methods.

### SUMMARY OF THE INVENTION

The VCSEL (Vertical Cavity Surface Emitting Laser) structure of the present invention is characterised by what is presented in claim 1.

The VCSEL structure has a vertical optical axis for emitting light along it. The VCSEL structure comprises a lower electrical contact layer, a lower and an upper mirror structure forming an optical resonant cavity between them above the lower contact layer, an active layer within said resonator, and an upper electrical contact layer above said resonator. At least one cross-section of the VCSEL structure in a perpendicular direction with respect to said optical axis comprises a mode selecting shape which promotes output of the fundamental transverse mode of the resonator while suppressing output of the higher modes.

According to the present invention, the mode selecting shape comprises a longitudinal portion which is directed past the optical axis and has a one-sided broadening forming, possibly together with the longitudinal portion, a central area around the optical axis. Being directed past the optical axis means that an imaginary centre line of the longitudinal portion or an extension of it does not hit the optical axis. Thus, the resultant shape lies, at least in one direction, asymmetrically with respect to the optical axis. One-sided means that along the side of the longitudinal portion opposite to the broadening there are no abrupt turns or steps but the side line continues smoothly to the area of the broadening. The broadening can have, for example, a rectangular shape being directed in parallel to the longitudinal portion.

Further, according to the present invention, the accurate geometry of the mode selecting shape is chosen to concentrate the fundamental transverse mode of the resonator in the central area while guiding the possible higher modes away from it through the longitudinal portion. Guiding the higher transverse modes means that the longitudinal portion can itself act as a mode sink for those modes or it can connect the higher order modes to a separate mode sink structure arranged in the peripheral area of the VCSEL structure. Due to the mode sink effect, the fields of the higher order transverse modes are spread to a significantly larger xy-area than the fundamental mode field, which efficiently suppresses the lasing of the higher order modes. In order to further enhance the suppression of the higher order modes the longitudinal portion or the separate mode sink(s) can optionally include areas of higher loss, lower gain, lower reflection or different cavity length compared to the central area.

With the non-cylindrical mode selecting shape of the present invention, it is possible to achieve real single mode operation of a VCSEL with high beam quality, the beam size and output power clearly exceeding those achievable by conventional cylinder symmetric VCSEL structures.

In one preferred embodiment, the broadening lies at a distance from the ends of the longitudinal portion. In other words, in this embodiment the longitudinal portion forms two longitudinal mode sink parts extending into opposite directions from the central area. This geometry provides particularly effective damping of the higher modes. In more detail, the geometry of this kind of mode selecting shape can be substantially T-shaped with the base and the branches of the T being formed by the broadening and the longitudinal portion, respectively. The efficiency of this kind of geometry of a light guiding structure in ensuring single mode operation with a wide cross section of the confined intensity has been proven in the field of rib waveguides. Referring to the terminology commonly used with rib waveguides, the central area corresponds to the rib and the mode sink parts or the branches of the T-shape correspond to the surrounding slab waveguide. With this kind of resonator geometry, the fundamental transverse mode propagates back and forth along the rib type central area with small losses. All the higher order transverse modes spread much further into the slab waveguide-like mode sink parts. These mode sink parts, or separate mode sink regions behind them, thus prevent the higher modes from lasing.

In the T-like geometry described above, thickness h of the branches, height H of the T and width w of the base fulfil the conditions

$$\frac{W}{H} < 0.3 + \frac{h / H}{\sqrt{1 - {( h / H )}^{2}}}$$

and h/H 0.5. These are known as Soref's equations in the field of rib waveguides. Those conditions ensure that lasing of any higher order transverse modes in the horizontal directions of the VCSEL layer structure is prevented, thus ensuring single-mode operation of the component.

Alternatively, the broadening can lie at one of the ends of the longitudinal portion. The shape of the broadening does not need to be rectangular but it can form, for example, a circular central area at the end of the longitudinal portion. In order to enhance the mode sinking function, in one preferable embodiment, the mode selecting shape comprises preferably at least two divergent longitudinal portions having their broadenings substantially coincided to form a single central area. For example, effective mode selection can be achieved by four longitudinal portions with adjacent longitudinal portions being directed perpendicular to each other.

With the principles of the mode selecting shape according to the present invention, it is of standard procedure for a person skilled in the art to choose the actual geometry and dimensions so as to realise the mode selection function defined above. Thus, no detailed description concerning it is needed here. The accurate determination of the mode selecting shape can be performed e.g. by means of a computing software designed to calculate the electromagnetic fields in waveguides and other optical structures.

The mode selecting shape according to the present invention can be arranged in different layers or regions of the VCSEL. In one preferred embodiment, it is arranged as an aperture in the upper contact region confining the output. In addition to current guiding, the aperture also cuts off from the output possible higher lasing modes extending outside the central area.

According to another preferable feature of the present invention, the mode selecting shape is arranged as a current guiding structure between the contact regions. By guiding directly the current, the lasing operation can be effectively controlled according to the desired geometry of the mode selecting shape.

On the other hand, in one preferred embodiment, the mode selecting shape is arranged as a reflectance modifying structure in at least one of the upper and lower mirrors. In other words, the reflectance can be optimised within the mode selecting shape but set lower out of it, thus providing effective lasing within said shape only.

Preferably, the mode selecting shape is arranged as a light guiding structure within the optical resonant cavity. In the vertical direction, the shape can cover a significant portion of the VCSEL's height, the shape then acting as a waveguide effectively confining the lasing operation within the shape. Both the reflectance modifying and the light guiding properties of the VCSEL structure can be realised by means of refractive index variations between the interior and exterior of the mode selecting shape.

The mode selecting shape can be arranged simultaneously in all those parts of a VCSEL mentioned above. On the other hand, in one possible approach, the optical cavity is formed according to the mode selecting shape but the aperture of the upper contact is circular. Then possible higher modes due to imperfect mode selection are cut off by the aperture.

### BRIEF DESCRIPTION OF THE DRAWINGS

The accompanying figures, which are included to provide a further understanding of the invention and constitute a part of this specification, illustrate embodiments of the invention as well as prior art examples and, together with the description, help to explain the principles of the invention.

FIG. 1 represents a typical prior art VCSEL structure.

FIG. 2 shows a VCSEL structure according to one preferred embodiment of the present invention.

FIGS. 3a-3c illustrates examples of preferred geometries of the mode selecting shapes according to the present invention.

### DETAILED DESCRIPTION OF THE INVENTION

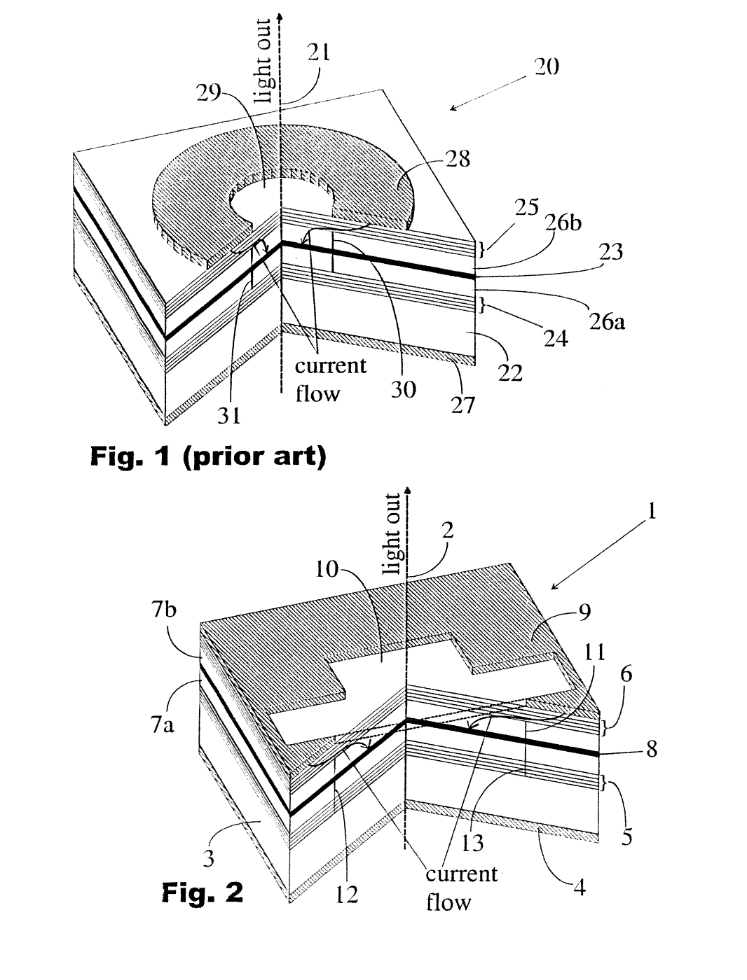

The structure and operation of a typical VCSEL 20 is illustrated in FIG. 1. At first, the vertical structure and operation of the component are discussed. This discussion is focused on the optical axis 21 of the VCSEL, which is shown as a dashed line in FIG. 1. The VCSEL layer structure lies on top of a semiconductor substrate 22. In the core of the structure is an active layer 23, which typically includes one or more quantum wells. The active layer is sandwiched between a lower and an upper mirror 24, 25. Typically, the mirrors are formed as distributed Bragg reflectors (DBR), each consisting of a multilayer stack of thin films having alternating refractive indices and one quarter wavelength thicknesses. Between the mirrors and the active layer are usually lower and upper spacer layers 26a, 26b which in turn can be made of one or more thin films. The outermost layers are a lower and an upper contact layer 27, 28 for feeding current through the VCSEL structure.

VCSELs are usually fabricated on top of semiconductor wafers by using various semiconductor processing steps like epitaxial layer growth, metal deposition, dielectric deposition, lithographic patterning, etching, annealing, oxidation and diffusion. Usually plane projections of the aimed VCSEL structures are first lithographically defined on top of the wafer, i.e. into the xy-plane. Then these xy-patterns are transformed into three dimensional (3D) structures by using other semiconductor processing steps comprising, for example, etching. An example of a 3D structure is the ring-shaped upper contact layer 28 in FIG. 1. Some process steps can also be carried out before the first lithography step to create one dimensional (1D) structures that only vary along the vertical z-axis that is perpendicular to the surface of the semiconductor wafer.

In operation, electrical current flowing into the active layer 23 first generates photons via spontaneous emissions. The photons then bounce back and forth between the lower and upper mirror stacks 24, 25, i.e. resonate in the laser cavity. When electrical current and photons both pass through the active layer they produce stimulated emission, i.e. identical copies of the original photons. The gain of the active layer 23 increases as a function of the injected electrical current and above the threshold current the stimulated emission starts to dominate the spontaneous emission, and the VCSEL 20 starts to lase. Then the gain of the active layer is larger than the optical losses within and out of the cavity. The finite reflectivity of the mirrors 24, 25 enables some of the light to escape from the cavity. This also produces the optical output of the VCSEL, which is typically collected through the upper mirror 25. In some cases, the output can also be collected through the lower mirror 24. The vertical cavity of a VCSEL 20 is typically so thin that it only supports one longitudinal mode.

In the following, the 3D structure and operation of a typical VCSEL are explained. As stated above, the output is usually collected through the upper mirror and the layers below the active layer are electrically conductive. Then the lower contact can be easily realised at the backside of the substrate as shown in FIG. 1. However, it is difficult to make an optically transparent electrical contact on top of the upper mirror. Thus, as shown in FIG. 1, the upper contact is typically realised as a patterned metal layer 28 having an optical aperture 29.

In some known examples of VCSELs, all the layers within the laser cavity are uniform in the xy-plane, i.e. they do not have any transverse structures that would guide either light or current. In such VCSELs the current flow from the upper contact to the active layer depends strongly on the geometry of the upper contact. The flow of the current into a limited part of the active layer according to the upper contact layer geometry induces the localisation of the transverse gain profile, and this leads to the localisation of the spontaneous emission. The localised light emission, the reflections from the mirrors, and the nonlinear properties of the materials locally increase the refractive index in the vicinity of the optical axis, thus creating an optical waveguide into the laser cavity. The resulting VCSEL is then said to be gain-guided. The waveguide formed by the resonating optical beam itself has a very small refractive index contrast that changes as a function of the current.

The VCSEL of FIG. 1 represents another approach. There is arranged a current guiding structure 30 within the component by inducing transverse conductivity variations into the upper spacer layer 26b. Similar structures could also be arranged into the other layers between the upper contact 28 and the active layer 23. The conductivity of the layers can be locally modified e.g. by using implantation or oxidation. Alternatively, parts of the layers can be etched away and optionally replaced with other materials. To one skilled in the art, all these methods are well known. Examples of known current constriction and current confinement structures can be found e.g. in U.S. Pat. No. 6,751,245 and No. 5,412,680. With the patterned upper contact and the additional current guiding structures, the current flow can be directed to a limited part of the active layer and the transverse gain profile can be optimised. This enables the reduction of both the threshold current and the optical response time of the VCSEL.

In some known examples of VCSELs, as also shown in FIG. 1, the resonating optical beam is confined by transverse refractive index structures 31 that form an optical waveguide between the upper and lower mirrors. In contrast to the gain-guided VCSELs, these VCSELs are said to be index-guided. The trans-verse refractive index structures 31 can be fabricated similarly to the current guiding structures described above, and in some cases the same structures guide both current and light. Typically the refractive index contrast is larger in index-guided VCSELs than in gain-guided VCSELs. However, the nonlinear effects can also change the refractive index contrast of an index-guided VCSEL as a function of the current, and some VCSELs can represent a combination of gain- and index-guiding.

As illustrated in FIG. 1, the optical aperture 29 and possible structures 30, 31 guiding the current and light are usually cylinder symmetric around the optical axis 21. In fact, the entire VCSEL stack 20 is often formed as a cylindrical pillar on a substrate. With cylinder symmetric structures, there is the problem that the cross section of the cylindrical structures as well as the injected current has to be kept relatively small in order to keep the operation single-mode. This means limited output power.

Also some non-cylindrical VCSELs are known. However, the excursion from the cylinder symmetry is usually used to stabilise the polarisation of the VCSEL's output, and such VCSELs are often actually symmetric with respect to both the x- and the y-axis. Examples of such VCSELs can be found e.g. in U.S. Pat. No. 5,412,680. Except for the PhC-type VCSELs discussed above, the lack of cylinder-symmetry has not been intended to increase the output power or the output beam width of single-mode VCSELs.

The schematic in FIG. 2 shows a VCSEL 1 having a layer structure similar to that of FIG. 1. The component is designed to emit light along the optical axis 2. At the bottom side of a semiconductor substrate 3 is a lower contact layer 4. The optical cavity is formed by a lower and an upper stack of thin films forming a lower and an upper mirror 5, 6. Between them, separated from the mirrors by spacer layers 7a, 7b is an active layer 8 for generating light. On top of the structure is an upper contact layer 9 having an aperture 10 around the optical axis 2 for the output of the laser. In the upper spacer layer there is a current guiding structure 11 for confining the current flow near the optical axis 2. In the lower spacer layer 7a there is an optical confining structure 12 which is realised as refractive index variations. In addition, the lower mirror 5 comprises a reflectance modifying structure 13 providing high reflectivity near the optical axis 2 only. Thus, the lasing operation is effectively confined to the vicinity of the optical axis 2.

As a fundamental difference between the VCSEL of FIG. 2 and the prior art component shown in FIG. 1, the geometries of the aperture 10 and other guiding structures 11, 12, 13 are not circular. Instead, in the plane perpendicular to the optical axis 2, each of them is substantially T-shaped, the T being rather wide. In the direction parallel to the base of the T, each of said structure lies in a position where imaginary centre lines of the branches of the T are directed past the optical axis. Instead, in the direction parallel to the branches of the T, the geometries are located symmetrically with respect to the optical axis 2. The branches of the T act as mode sinks guiding the higher lateral modes away from the optical axis, thus ensuring single mode output of the VCSEL. With this kind of geometry of the mode selecting shape it is possible to maintain single mode operation with a beam size outstandingly bigger than with conventional circular symmetry. In addition, geometries of this kind can be realised by standard manufacturing steps without any special procedures.

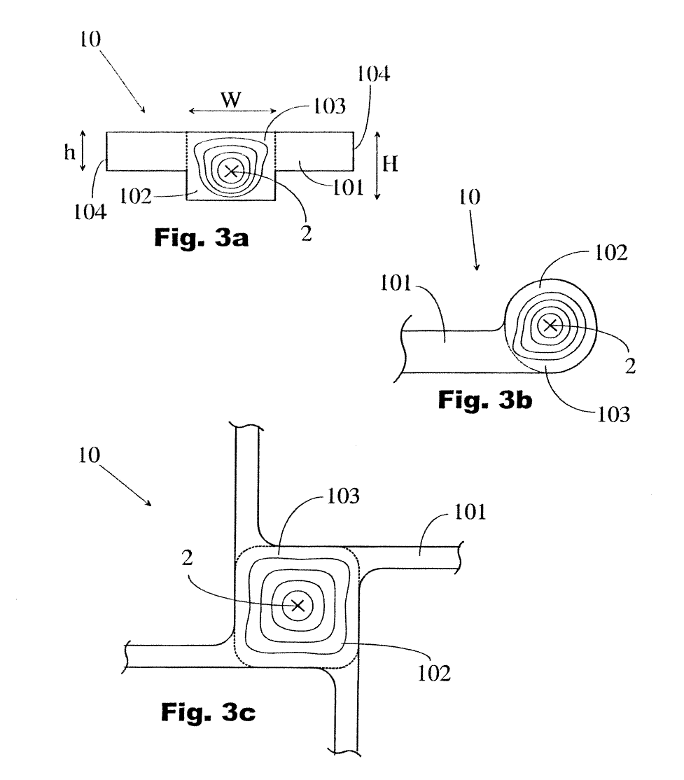

Examples of different mode selecting shapes 10 according to the present invention are illustrated in FIGS. 3a-3c. Each of them comprises a longitudinal portion 101 having a one-sided broadening 102 so that at the broadening there is formed a central area 103 for concentrating the fundamental mode within it. The longitudinal portion is directed so that the imaginary centre line of it goes past the optical axis 2. In the lengthwise direction of the longitudinal portion, the optical axis 2 lies substantially in the middle of the broadening 102. In FIG. 3a, the broadening lies at an equal distance from each of longitudinal portion ends 104 so that the mode selecting shape is similar to a wide letter T. In the mode selecting shapes of FIGS. 3b and 3c, the broadening 102 lies at the end of the longitudinal portion 101. The shape shown in FIG. 3c comprises actually four identical sub-shapes having their central areas 103 coincided and longitudinal portions directed perpendicular to each other. The outline of the mode selecting shape at the broadening can have abrupt steps like in FIG. 3a but all changes of directions in it can be rounded as well, as in FIGS. 3b and 3c, either intentionally or due to the finite resolution of the fabrication process.

In more detail, each of the mode selecting shapes shown in FIGS. 3a-3c are dimensioned so as to confine the fundamental transverse mode to the central area 103 while guiding the higher modes away from the optical axis 2 through the longitudinal portion 101. The longitudinal portion itself can be designed to act as a mode sink damping the higher modes. Alternatively, the longitudinal portion can be linked to a particular mode sink structure. In particular, in the case of the T-shaped geometry of FIG. 3a, said guiding effect can be realised by choosing width W of the base, height H and thickness of the branches of the T so that the following conditions are fulfilled:

$$\frac{W}{H} < 0.3 + \frac{h / H}{\sqrt{1 - {( h / H )}^{2}}} , and h / H \geq 0.5 .$$

As illustrated by thin field lines in FIGS. 3a-3c, the intensity distribution of the fundamental transverse mode extends from the central area slightly into the longitudinal portion(s). However, this small imperfection is well compensated by the overall power and beam size achievable with the mode selecting shapes according to the present invention.

In general, designing the accurate shape parameters so as to achieve said mode selecting function can be done e.g. by a computing software for calculating fields in different kinds of light guiding structures.

It is obvious to a person skilled in the art that the basic idea of the invention may be implemented in various ways. The invention and its embodiments are thus in no way limited to the examples described above but they may vary within the scope of the claims.

1. A VCSEL (Vertical Cavity Surface Emitting Laser) structure having a vertical optical axis, the VCSEL structure comprising a lower electrical contact layer, a lower and an upper mirror structure forming an optical resonant cavity between them above the lower contact layer, an active layer within said resonator, and an upper electrical contact layer above said resonator, wherein at least one cross-section of the VCSEL structure perpendicular to the optical axis comprises a mode selecting shape promoting output of the fundamental transverse mode of the resonator while suppressing output of the higher modes, characterised in that the mode selecting shape comprises a longitudinal portion being directed past the optical axis and having a one-sided broadening forming a central area around the optical axis, the geometry of the mode selecting shape being chosen to concentrate the fundamental mode in the central area while guiding the possible higher modes away from the optical axis through the longitudinal portion.

2. A VCSEL structure (1) according to claim 1, characterised in that the broadening lies at a distance from the ends of the longitudinal portion.

3. A VCSEL structure according to claim 2, characterised in that the geometry of the mode selecting shape is substantially T-shaped with the base and the branches of the T being formed by the broadening and the longitudinal portion, respectively.

4. A VCSEL structure according to claim 3, characterised in that thickness h of the branches, height H of the T and width w of the base fulfil the conditions
$$\frac{W}{H} < 0.3 + \frac{h / H}{\sqrt{1 - {( h / H )}^{2}}} ,$$
and h/H≧0.5.

5. A VCSEL structure according to claim 1, characterised in that the broadening lies at one of the ends of the longitudinal portion.

6. A VCSEL structure according to claim 5, characterised in that the mode selecting shape comprises at least two divergent longitudinal portions having their broadenings substantially coincided to form a single central area.

7. A VCSEL structure according to claim 1, characterised in that the mode selecting shape is arranged as an aperture in the upper contact region.

8. A VCSEL structure according to claim 1, characterised in that the mode selecting shape is arranged in a current guiding structure between the contact regions.

9. A VCSEL structure according to claim 1, characterised in that the mode selecting shape is arranged in a reflectance modifying structure in at least one of the upper and lower mirrors.

10. A VCSEL structure according to claim 1, characterised in that the mode selecting shape is arranged in a light guiding structure within the optical resonant cavity.

11. A VCSEL structure according to claim 9, characterised in that the mode selecting shape is realised by means of a difference in the refractive index between the interior and exterior of the mode selecting shape.
